(19) United States
(12) Patent Application Publication
(10) Pub. No.: US 2026/0026331 A1
(43) Pub. Date: Jan. 22, 2026

(54) LOW RESISTANCE VIA STRUCTURE

(71) Applicant: International Business Machines Corporation, Armonk, NY (US)

(72) Inventors: Oscar van der Straten, Guilderland Center, NY (US); Koichi Motoyama, Clifton Park, NY (US); Chih-Chao Yang, Glenmont, NY (US)

(21) Appl. No.: 18/774,698

(22) Filed: Jul. 16, 2024

(51) Int. Cl. H01L 23/522; H01L 21/3105; H01L 21/768; H01L 23/528; H01L 23/532; H01L 23/64

(52) U.S. Cl. CPC H01L 23/5226; H01L 21/31053; H01L 21/76831; H01L 23/5283; H01L 23/53266; H01L 23/647

(57) ABSTRACT

Embodiments of present invention provide a semiconductor structure. The structure includes a metal via having a substantially hyperboloid exterior shape; and a dielectric layer surrounding the metal via, where the metal via includes a bottom portion and a top portion; the top portion includes an outer liner and an inner liner at sidewalls thereof; and the bottom portion is directly surrounded by the dielectric layer. A method of forming the same is also provided.

### BACKGROUND

The present application relates to manufacturing of semiconductor integrated circuits. More particularly, it relates to a low resistance via structure and method of forming the same.

A semiconductor integrated circuit generally includes active devices such as various types of transistors in a front-end-of-line (FEOL) region and interconnect structures in a back-end-of-line (BEOL) region that provides power supply and signal routing functions for the transistors at the FEOL region. For advanced semiconductor devices with multi-level interconnection, metal via structures are used to enable metal-to-metal contact between two metal levels.

Via structures typically include both a main body of conductive material and several suitable nucleation liners and/or barrier layers. The liners or barrier layers ensure adequate adhesion to the surrounding dielectric material as well as good nucleation and growth of the conductive material for the main body. However, materials used for the liners and/or barrier layers typically exhibit high resistivity and the presence of such high-resistivity liners and/or barrier layers results in a via of overall high resistance, which negatively impacts device performance.

### SUMMARY

Embodiments of present invention provide a semiconductor structure. The structure includes a metal via having a substantially hyperboloid exterior shape; and a dielectric layer surrounding the metal via, where the metal via includes a bottom portion and a top portion; the top portion includes an outer liner and an inner liner at sidewalls thereof; and the bottom portion is directly surrounded by the dielectric layer.

In one embodiment, the bottom portion and a central portion of the top portion include a same conductive material, and the conductive material extends continuously from the top portion to the bottom portion.

In another embodiment, the central portion of the top portion is directly surrounded by the inner liner, the inner liner is surrounded by the outer liner, and the outer liner is surrounded by the dielectric layer.

In yet another embodiment, a portion of the inner liner extends into the bottom portion but stays away from sidewalls of the bottom portion.

In one embodiment, the conductive material is tungsten (W), ruthenium (Ru), iridium (Ir), molybdenum (Mo), or copper (Cu); the outer liner is made of titanium (Ti), titanium-nitride (TiN), tantalum (Ta), or tantalum-nitride (TaN); and the inner liner is made of Ru, ruthenium-tantalum (RuTa), Ir, iridium-tantalum (IrTa), cobalt (Co), or cobalt-tantalum (CoTa).

In one aspect, sidewalls of the bottom portion lean inwardly and the sidewalls of the top portion lean outwardly. In another aspect, a horizontal cross-section of the metal via at a bottom of the top portion is equal to or smaller than a horizontal cross-section of the metal via at a top of the bottom portion.

Embodiments of present invention also provide a method of forming a semiconductor structure. The method includes forming a first portion of a metal via with a conductive material, the first portion of the metal via having a conical frustum shape and being formed on top of a metal line; covering the first portion of the metal via with a dielectric layer; creating an opening in the dielectric layer, the opening exposing a top surface of the first portion of the metal via; forming an outer liner covering sidewalls of the opening; forming an inner liner on top of and covering the outer liner; and filling the opening surrounded by the inner liner with the conductive material to form a second portion of the metal via.

In one embodiment, forming the first portion of the metal via includes depositing a layer of the conductive material on top of the metal line; and patterning the layer of the conductive material, through a subtractive patterning process, by removing a portion of the layer of the conductive material to cause a remaining portion of the layer of the conductive material to form the first portion of the metal via.

In one embodiment, forming the outer liner includes depositing a conformal layer of a first liner material covering sidewalls of the opening and the exposed top surface of the first portion of the metal via; and removing a horizontal portion of the conformal layer of the first liner material to expose the top surface of the first portion of the metal via, thereby leaving the conformal layer of the first liner material at the sidewalls of the opening to form the outer liner.

In one aspect, removing the horizontal portion of the conformal layer further includes removing a portion of the first portion of the metal via exposed by the removal of the horizontal portion of the conformal layer to create a recess in the first portion of the metal via.

In another aspect, forming the inner liner includes forming the inner liner covering sidewalls of the recess in the first portion of the metal via.

In yet another aspect, filling the opening surrounded by the inner liner includes filling the recess with the conductive material to form a bottom portion of the metal via with rest of the first portion of the metal via, and filling the opening surrounded by both the inner liner and the outer liner with the conductive material to form a top portion of the metal via.

In one embodiment, the metal line is embedded in an interlevel-dielectric (ILD) layer and the method further includes forming a cap layer on top of the ILD layer, the cap layer surrounding a bottom section of the first portion of the metal via.

In one aspect, forming the cap layer includes depositing a layer of capping material covering the first portion of the metal via and on top of the ILD layer; planarizing the layer of capping material through a chemical-mechanical-polishing (CMP) process to expose a top surface of the first portion of the metal via; and recessing the layer of capping material to form the cap layer, wherein a top surface of the cap layer is below the top surface of the first portion of the metal via.

Embodiments of present invention provide a semiconductor structure. The structure includes a metal via having a bottom portion and a top portion; and a dielectric layer surrounding the metal via, where the bottom portion of the metal via has a conical frustum shape and is directly surrounded by the dielectric layer, and the top portion of the metal via has an inverted conical frustum shape and includes an outer liner and an inner liner at sidewalls thereof.

### BRIEF DESCRIPTION OF THE DRAWINGS

The present invention will be understood and appreciated more fully from the following detailed description of embodiments of present invention, taken in conjunction with accompanying drawings of which:

FIGS. 1-14 are demonstrative illustrations of cross-sectional views of a semiconductor structure in a process of manufacturing thereof according to one embodiment of present invention;

FIGS. 15-19 are demonstrative illustrations of cross-sectional views of a semiconductor structure in a process of manufacturing thereof according to another embodiment of present invention; and

FIG. 20 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

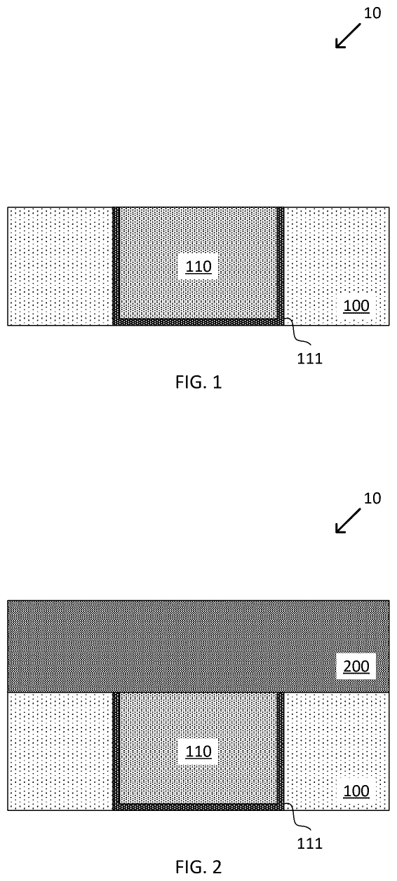

FIG. 1 is a demonstrative illustration of a cross-sectional view of a semiconductor structure in a step of manufacturing thereof according to one embodiment of present invention. More particularly, embodiments of present invention provide receiving or forming a semiconductor structure 10 that includes a metal line 110 embedded in or surrounded by an interlevel-dielectric (ILD) layer 100. The metal line 110 may be, for example, a M1, M2, or Mx metal line in a back-end-of-line (BEOL) structure and may be made of or made to contain, for example, tungsten (W), copper (Cu), aluminum (Al) or other suitable conductive materials. The metal line 110 may be surrounded by a metallic liner 111, which may be made of, for example, titanium (Ti), titanium-nitride (TiN), tantalum (Ta), tantalum-nitride (TaN) or other suitable liner materials. The ILD layer 100 surrounding the metal line 110 may be a layer of dielectric material such as, for example, silicon-oxide (SiOx), silicon-nitride (SiN), silicon-carbide (SiC), silicon-oxycarbide (SiOC), silicon-carbonitride (SiCN), silicon-oxycarbonitride (SiOCN), silicon-boron-carbonitride (SiBCN), and more preferably may be a layer of low-k dielectric material with a low dielectric constant. The metal line 110 and the surrounding ILD layer 100 may have or may be formed to have a coplanar top surface.

FIG. 2 is a demonstrative illustration of a cross-sectional view of a semiconductor structure in a step of manufacturing thereof according to one embodiment of present invention. More particularly, following the step illustrated in FIG. 1, embodiments of present invention provide forming a layer 200 of conductive material on top of the top surface of the metal line 110 and the ILD layer 100. The conductive material of the layer 200 may include, for example, ruthenium (Ru), molybdenum (Mo), rhodium (Rh), iridium (Ir), or nickel (Ni), and may also be W, Cu, or Al if the metal line 110 is not correspondingly W, Cu, or Al. In other words, the layer 200 of conductive material may include a material that is different from that of the metal line 110 underneath thereof. The layer 200 of conductive material may be formed through any currently existing or future developed deposition process such as, for example, a chemical-vapor-deposition (CVD) process, a physical-vapor-deposition (PVD) process, or an atomic-layer-deposition (ALD) process. After the deposition, a top surface of the layer 200 of conductive material may be planarized through, for example, a chemical-mechanical-polishing (CMP) process.

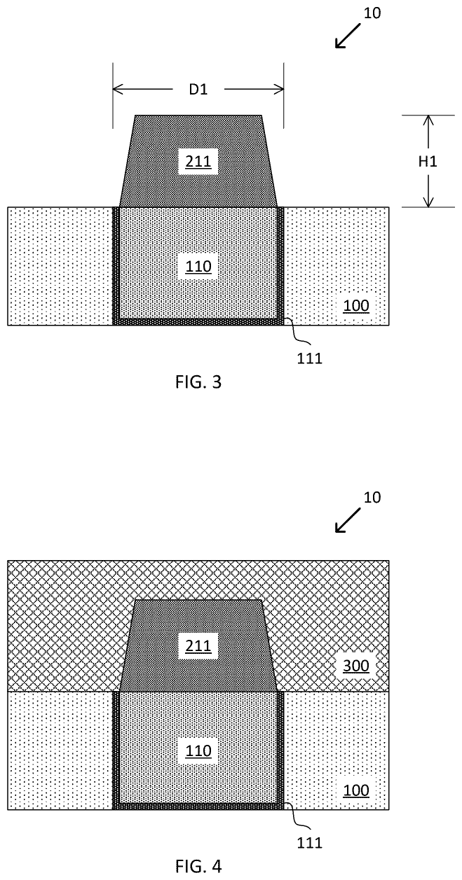

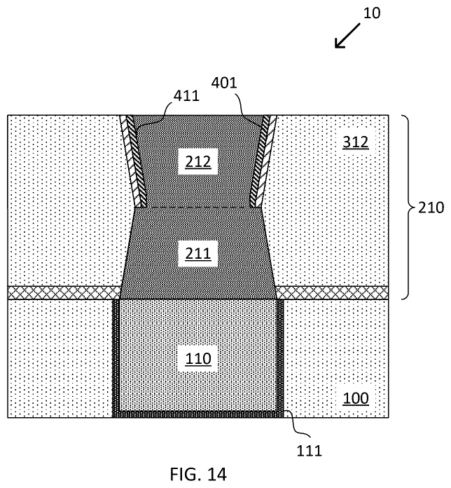

FIG. 3 is a demonstrative illustration of a cross-sectional view of a semiconductor structure in a step of manufacturing thereof according to one embodiment of present invention. More particularly, following the step illustrated in FIG. 2, embodiments of present invention provide patterning the layer 200 to form a first portion of a metal via. More particularly, the layer 200 may be patterned through, for example, a subtractive patterning process by selectively removing a portion of the layer 200, leaving the remaining portion of the layer 200 to form a first portion 211 of a metal via 210 (see FIG. 14). The first portion 211 of the metal via 210 may have a conical frustum shape, whose formation may be influenced by the nature of the subtractive patterning process. In other words, the first portion 211 of the metal via 210 may have a bigger bottom base and a smaller top base and have sidewalls that are not vertical and may lean inwardly.

In one embodiment, the bottom base of the first portion 211 of the metal via 210 may be formed to have a width D1 that is substantially the same as a width of the metal line 110 underneath thereof. However, embodiments of present invention are not limited in this aspect and the width D1 of the first portion 211 of the metal via 210 may be made different from, such as smaller than, that of the metal line 110. In the case of being a conical frustum shape, the width D1 of the bottom base of the first portion 211 may be a diameter of the bottom base. The first portion 211 of the metal via 210 may have a height H1 ranging from about 10 nm to about 100 nm. More particularly, the first portion 211 may have an aspect ratio of its height H1 over its width D1 at the bottom base, and the aspect ratio may range from about 2:1 to about 10:1.

FIG. 4 is a demonstrative illustration of a cross-sectional view of a semiconductor structure in a step of manufacturing thereof according to one embodiment of present invention. More particularly, following the step illustrated in FIG. 3, embodiments of present invention provide forming a layer 300 of capping material on top of the ILD layer 100 and covering the first portion 211 of the metal via 210. In other words, the layer 300 of capping material may be formed to have a height that is higher than the height H1 of the first portion 211 of the metal via 210. In one embodiment, the capping material may be, for example, SiN or SiCN and may be formed through a deposition process such as a CVD process, a PVD process, or an ALD process.

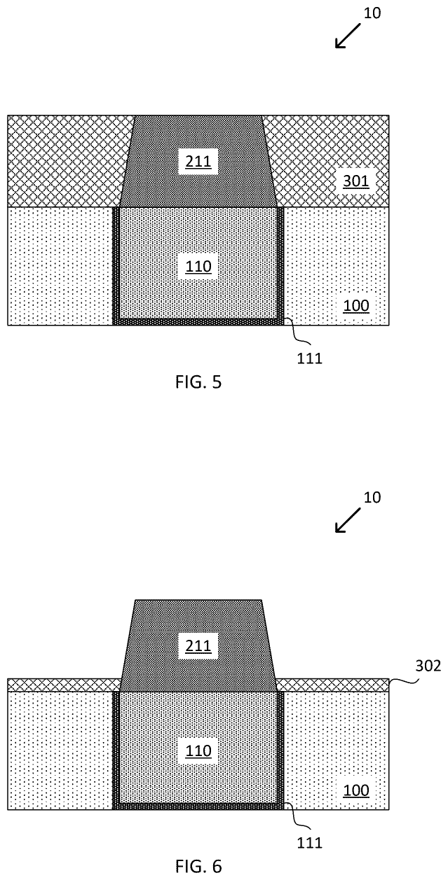

FIG. 5 is a demonstrative illustration of a cross-sectional view of a semiconductor structure in a step of manufacturing thereof according to one embodiment of present invention. More particularly, following the step illustrated in FIG. 4, embodiments of present invention provide planarizing a top surface of the layer 300 through, for example, a CMP process. In one embodiment, the planarization process may expose a top surface of the first portion 211 of the metal via 210 and reduce the height of the layer 300 to be the same as the height H1 of the first portion 211 of the metal via 210. The layer 300 becomes a layer 301.

FIG. 6 is a demonstrative illustration of a cross-sectional view of a semiconductor structure in a step of manufacturing thereof according to one embodiment of present invention. More particularly, following the step illustrated in FIG. 5, embodiments of present invention provide continuing to recess the height of the layer 301 of capping material. The recessing process eventually reduces the height of the layer 301 to be around, for example, 5 nm to 10 nm thereby producing or resulting a capping layer 302 surrounding a bottom section of the first portion 211 of the metal via 210. The capping layer 302 may cover portions of the metal line 110 that are not directly underneath the metal via 210, such as portions that exist into the paper. The capping layer 302 prevents elements of the metal line 110 from diffusing into the dielectric material to be formed on top of the capping layer 302.

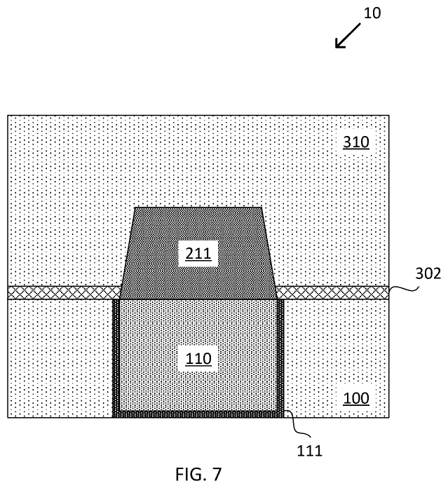

FIG. 7 is a demonstrative illustration of a cross-sectional view of a semiconductor structure in a step of manufacturing thereof according to one embodiment of present invention. More particularly, following the step illustrated in FIG. 6, embodiments of present invention provide forming an ILD layer 310 on top of the ILD layer 100, via the capping layer 302, and on top of and surrounding the first portion 211 of the metal via 210. The ILD layer 310 may be a layer of SiOx, SiN, SiC, SiOC, SiCN, SiOCN, or SiBCN and may be formed to have a height that is substantially close to, or higher than, the height of the metal via 210, which includes the first portion 211 and a second portion to be formed on top thereof. For example, in one embodiment, the ILD layer 310 may have a height ranging from about 30 nm to about 100 nm.

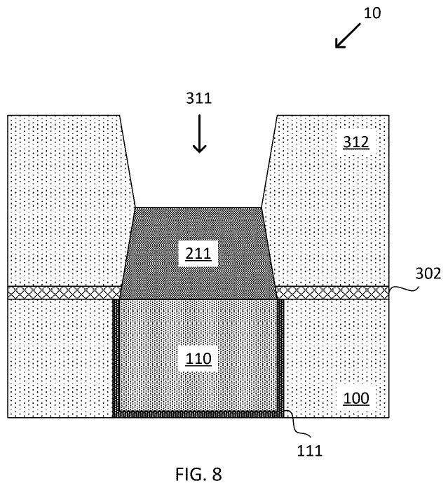

FIG. 8 is a demonstrative illustration of a cross-sectional view of a semiconductor structure in a step of manufacturing thereof according to one embodiment of present invention. More particularly, following the step illustrated in FIG. 7, embodiments of present invention provide creating an opening 311 in the ILD layer 310 through, for example, a lithographic patterning and etch process. The opening 311 may have a depth ranging from about 10 nm to about 50 nm and, by nature of the etch process, may have an inverted conical frustum shape with sidewalls leaning outwardly. In other words, the opening 311 may have a top cross-sectional area that is bigger than a bottom cross-sectional area. In one embodiment, the opening 311 is substantially aligned with the first portion 211 of the metal via 210 and the bottom cross-sectional area may be substantially equal to the top surface of the first portion 211 of the metal via 210. In another embodiment, the bottom cross-sectional area of the opening 311 may be less than the top surface of the first portion 211 of the metal via 210.

The creation of the opening 311 results in a dielectric layer 312, from the ILD layer 310, that may directly surround both a bottom portion and a top portion of the metal via 210 as being described below in more details. Here, the terms “bottom portion” and “top portion” do not necessarily mean exact half or 50% of the height of the metal via 210. Rather, these terms are used to indicate that the metal via 210 may be made of two portions, that is, a bottom-portion and a top-portion.

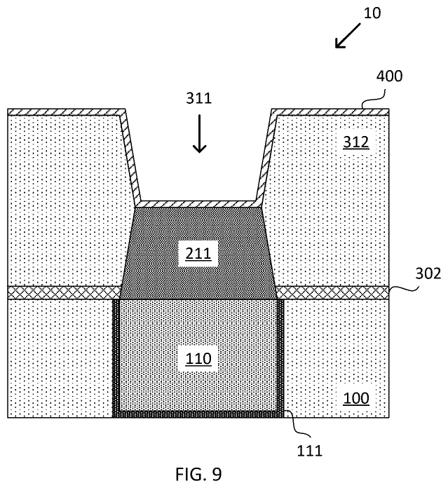

FIG. 9 is a demonstrative illustration of a cross-sectional view of a semiconductor structure in a step of manufacturing thereof according to one embodiment of present invention. More particularly, following the step illustrated in FIG. 8, embodiments of present invention provide forming a conformal layer 400 of liner material covering the opening 311 in the dielectric layer 312, in particular covering sidewalls of the opening 311. The liner material of the conformal layer 400 may include, for example, titanium (Ti), titanium-nitride (TiN), tantalum (Ta), tantalum-nitride (TaN), a combination of one or more thereof, or other suitable liner materials. The conformal layer 400 of liner material may be formed through, for example, a deposition process such as those described above and may be formed to have a thickness ranging from about 1 nm to about 5 nm.

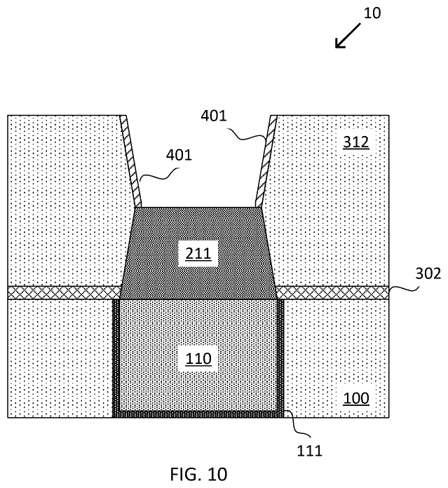

FIG. 10 is a demonstrative illustration of a cross-sectional view of a semiconductor structure in a step of manufacturing thereof according to one embodiment of present invention. More particularly, following the step illustrated in FIG. 9, embodiments of present invention provide applying a directional and/or anisotropic etch process to remove horizontal portions of the conformal layer 400 of covering material. More specifically, the etch process, such as a reactive-ion-etch (RIE) process, may remove a portion of the conformal layer 400 directly above the first portion 211 of the metal via 210 and remove other portions that cover the top surface of the dielectric layer 312. The etch process thereby creates an outer liner 401 directly next to and against the sidewalls of the opening 311 surrounded by the dielectric layer 312. In one embodiment, the etch process may be a selective etch process to leave the first portion 211 of the metal via 210 substantially unetched.

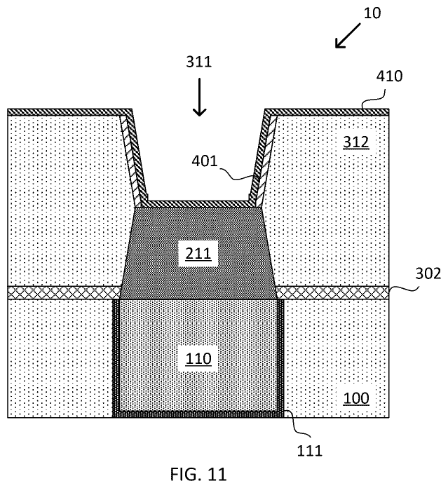

FIG. 11 is a demonstrative illustration of a cross-sectional view of a semiconductor structure in a step of manufacturing thereof according to one embodiment of present invention. More particularly, following the step illustrated in FIG. 10, embodiments of present invention provide forming a conformal layer 410 of liner material covering the remaining opening 311 which is now surrounded by the outer liner 401. The liner material of the conformal layer 410 may include, for example, Ru, RuTa, Ir, IrTa, Co, CoTa, or a combination of one or more thereof, and may be different from that of the outer liner 401. The conformal layer 410 of liner material may be formed through, for example, a deposition process such as those described above and may be formed to have a thickness ranging from about 1 nm to about 5 nm.

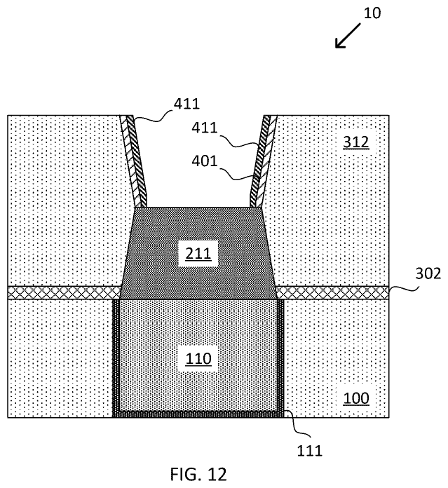

FIG. 12 is a demonstrative illustration of a cross-sectional view of a semiconductor structure in a step of manufacturing thereof according to one embodiment of present invention. More particularly, following the step illustrated in FIG. 11, embodiments of present invention provide applying a directional and/or anisotropic etch process to remove horizontal portions of the conformal layer 410 of covering material. Similar to forming the outer liner 401, the etch process may remove a portion of the conformal layer 410 directly above the first portion 211 of the metal via 210 and remove other portions that cover the top surface of the dielectric layer 312. The etch process thereby creates an inner liner 411 directly next to and against the outer liner 401. In one embodiment, the outer liner 401 and the inner liner 411 may have a substantially same height, measured vertically.

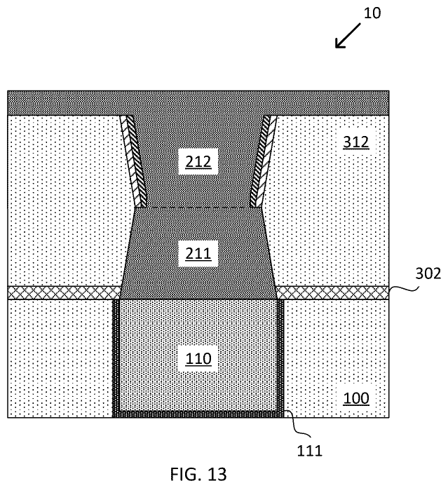

FIG. 13 is a demonstrative illustration of a cross-sectional view of a semiconductor structure in a step of manufacturing thereof according to one embodiment of present invention. More particularly, following the step illustrated in FIG. 12, embodiments of present invention provide filling the remaining opening 311 that is surrounded by both the inner liner 411 and the outer liner 401 with a conductive material to form a second portion 212 of the metal via 210. Embodiments of present invention provide applying the same conductive material as that used in forming the first portion 211 of the metal via 210 in forming the second portion 212 of the metal via 210. By applying the same conductive material, the metal via 210 may have the conductive material extending from the second portion 212 to the first portion 211 continuously. In other words, no liners or other adhesive materials may be needed in-between the first portion 211 and the second portion 212 of the metal via 210, which would otherwise result in extra resistance of the metal via 210.

FIG. 14 is a demonstrative illustration of a cross-sectional view of a semiconductor structure in a step of manufacturing thereof according to one embodiment of present invention. More particularly, following the step illustrated in FIG. 13, embodiments of present invention provide removing any excessive conductive material that were deposited on top of the dielectric layer 312. For example, a CMP process may be applied to polish off or remove the conductive material such that the second portion 212 of the metal via 210 may have a top surface that is coplanar with the top surface of the dielectric layer 312.

As is demonstratively illustrated in FIG. 14, the metal via 210 may include a first portion 211 and a second portion 212, as indicated by the dotted line in FIG. 14, which may be referred to as a bottom portion 211 and a top portion 212 of the metal via 210 as well. In one embodiment, the bottom portion 211 and the top portion 212 may each have a height that is substantially close to 50% of a height of the metal via 210, which may be strategic for forming the metal via 210 with a minimum horizontal dimension. The metal via 210 may have a substantially hyperboloid exterior shape, formed by the bottom portion 211 of a conical frustum shape and the top portion 212 of an inverted conical frustum shape.

In one embodiment, only the top portion 212 of the metal via 210 includes an inner liner 411 and an outer liner 401, with the inner liner 411 directly surrounding a central portion of the top portion 212 of the metal via 210, the outer liner 401 surrounding the inner liner 411, and the dielectric layer 312 surrounding the outer liner 401. On the other hand, the bottom portion 211 of the metal via 210 may be directly surrounded by the dielectric layer 312, while a bottom section of the bottom portion 211 of the metal via 210 may be surrounded by the capping layer 302.

In one embodiment, a bottom surface or bottom cross-section of the top portion 212 of the metal via 210 may have a substantially same area size as a top surface or top cross-section of the bottom portion 211 of the metal via 210, thereby forming a smooth and continuous transition, in cross-sectional area, from the top portion 212 to the bottom portion 211 or vise versus. However, embodiments of present invention are not limited in this aspect and the bottom cross-section of the top portion 212 and the top cross-section of the bottom portion 211 may be different in size, resulting in a discontinuous change in cross-sectional area of the metal via 210.

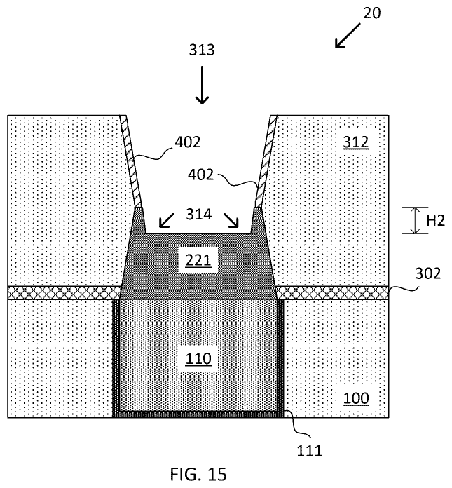

FIG. 15 is a demonstrative illustration of a cross-sectional view of a semiconductor structure 20 in a step of manufacturing thereof according to another embodiment of present invention. More particularly, starting from the semiconductor structure 10 and following the step illustrated in FIG. 9, embodiments of present invention provide applying a directional and/or anisotropic etch process to remove horizontal portions of the conformal layer 400 of covering material. More specifically, the etch process, such as a reactive-ion-etch (RIE) process, may remove a portion of the conformal layer 400 directly above the first portion 211 of the metal via 210 and remove portions that cover the top surface of the dielectric layer 312. The process thereby creates an outer liner 402 directly next to and against the sidewalls of the opening 311 that is surrounded by the dielectric layer 312.

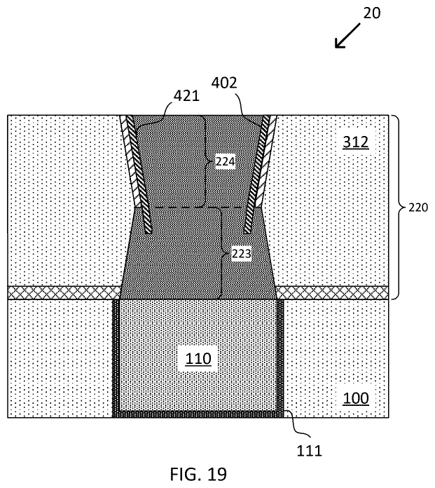

Embodiments of present invention provide further etching the exposed first portion 211 of the metal via 210, through the opening 311, to create an opening 313 that includes a recess 314 made into the first portion 211 of the metal via 210, thereby forming a first portion 221 of a metal via 220 (see FIG. 19). In other words, the opening 313 may have a depth that is deeper than the opening 311. In one embodiment, the recess 314 may have a depth H2 ranging from about 15 nm to about 40 nm.

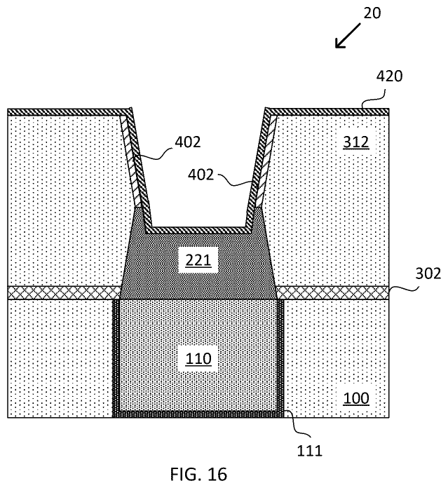

FIG. 16 is a demonstrative illustration of a cross-sectional view of a semiconductor structure in a step of manufacturing thereof according to another embodiment of present invention. More particularly, following the step illustrated in FIG. 15, embodiments of present invention provide forming a conformal layer 420 of liner material covering the opening 313 which is now partially surrounded by the outer liner 402 and partially embedded in the first portion 221 of the metal via 220. The liner material of the conformal layer 420 may be the same as that of the conformal layer 410 such as Ru, RuTa, Ir, IrTa, Co, CoTa, or a combination of one or more thereof, and may be different from that of the outer liner 402. The conformal layer 420 of liner material may be formed through, for example, a deposition process such as those described above and may be formed to have a thickness ranging from about 1 nm to about 5 nm.

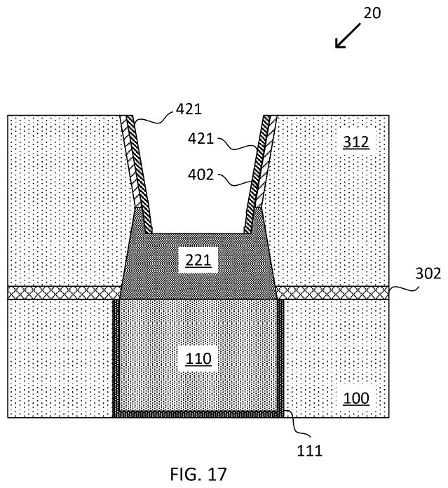

FIG. 17 is a demonstrative illustration of a cross-sectional view of a semiconductor structure in a step of manufacturing thereof according to another embodiment of present invention. More particularly, following the step illustrated in FIG. 16, embodiments of present invention provide applying a directional and/or anisotropic etch process to remove horizontal portions of the conformal layer 420 of covering material. Similar to forming the outer liner 402, the etch process may remove a portion of the conformal layer 420 horizontally in the recess 314 of the first portion 221 of the metal via 220 and remove other portions that cover the top surface of the dielectric layer 312. The process thereby creates an inner liner 421. In one embodiment, an upper portion of the inner liner 421 may be directly next to and against the outer liner 402 and a lower portion of the inner liner 421 may be next to and against sidewalls of the recess 314. However, the lower portion of the inner liner 421 stays away from sidewalls of the first portion 221 of the metal via 220, that is, outer sidewalls of the first portion 221 of the metal via 210.

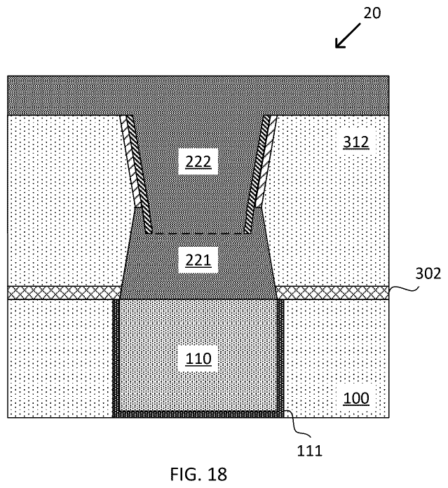

FIG. 18 is a demonstrative illustration of a cross-sectional view of a semiconductor structure in a step of manufacturing thereof according to another embodiment of present invention. More particularly, following the step illustrated in FIG. 17, embodiments of present invention provide filling the remaining opening 313 that is surrounded by the inner liner 421 with a conductive material to form a second portion 222 of the metal via 220. Embodiments of present invention provide applying the same conductive material as that used in forming the first portion 221 of the metal via 220 in forming the second portion 222 of the metal via 220. In applying a same conductive material, the conductive material extends continuously from the second portion 222 of the metal via 220 to the first portion 221 of the metal via 220. No liners or other adhesive material may be needed between the first portion 221 and the second portion 222 of the metal via 220, resulting in lower overall resistance of the metal via 220.

FIG. 19 is a demonstrative illustration of a cross-sectional view of a semiconductor structure in a step of manufacturing thereof according to another embodiment of present invention. More particularly, following the step illustrated in FIG. 18, embodiments of present invention provide removing any excessive conductive material on top of the dielectric layer 312. For example, a CMP process may be applied to polish off or remove the conductive material such that the second portion 222 of the metal via 220 has a top surface that is coplanar with the top surface of the dielectric layer 312.

As is demonstratively illustrated in FIG. 19, the metal via 220 may include a bottom portion 223 and a top portion 224, as indicated by the dotted line in FIG. 19, although each of them may not necessarily represent exact half or 50% of the metal via 220. The metal via 220 may have a substantially hyperboloid exterior shape, formed by the bottom portion 223 of conical frustum shape and the top portion 224 of an inverted conical frustum shape. In one embodiment, the top portion 224 may include an upper portion of the inner liner 421 and the outer liner 402, with the inner liner 421 directly surrounding a central portion of the top portion 224 of the metal via 220, the outer liner 402 surrounding the inner liner 411, and the dielectric layer 312 surrounding the outer liner 401.

On the other hand, a lower portion of the inner liner 421 may extend, from the top portion 224 into the bottom portion 223 of the metal via 220 but stays away from and not directly at sidewalls of the bottom portion 223 of the metal via 220. The bottom portion 223 of the metal via 220 is directly surrounded by the dielectric layer 312, while a bottom section of the bottom portion 223 may be surrounded by the capping layer 302.

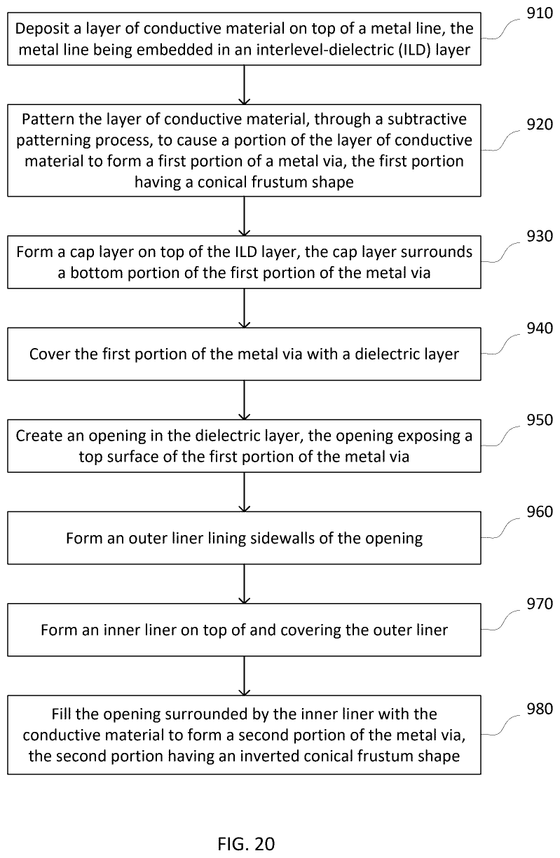

FIG. 20 is a demonstrative illustration of a flow-chart of a method of manufacturing an interconnect structure according to embodiments of present invention. The method includes (910) depositing a layer of conductive material on top of a metal line, the metal line being embedded in an interlevel-dielectric (ILD) layer; (920) patterning the layer of conductive material, through a subtractive patterning process, to remove a portion of and causing a remaining portion of the layer of conductive material to form a first portion of a metal via with the first portion having a conical frustum shape; (930) forming a cap layer on top of the ILD layer, the cap layer surrounding a bottom section of the first portion of the metal via; (940) covering the first portion of the metal via with a dielectric layer; (950) creating an opening in the dielectric layer, the opening exposing a top surface of the first portion of the metal via; (960) forming an outer liner covering sidewalls of the opening; (970) forming an inner liner on top of and covering the outer liner; and (980) filling the opening surrounded by the inner liner with the conductive material to form a second portion of the metal via, the second portion having an inverted conical frustum shape.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions above have been presented for the purposes of illustration of various embodiments of present invention and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a metal via having a substantially hyperboloid exterior shape; and
a dielectric layer surrounding the metal via,
wherein the metal via includes a bottom portion and a top portion; the top portion includes an outer liner and an inner liner at sidewalls thereof; and the bottom portion is directly surrounded by the dielectric layer.

2. The semiconductor structure of claim 1, wherein the bottom portion and a central portion of the top portion comprise a conductive material, and the conductive material extends continuously from the top portion to the bottom portion.

3. The semiconductor structure of claim 2, wherein the central portion of the top portion is directly surrounded by the inner liner, the inner liner is surrounded by the outer liner, and the outer liner is surrounded by the dielectric layer.

4. The semiconductor structure of claim 3, wherein a portion of the inner liner extends into the bottom portion but stays away from sidewalls of the bottom portion.

5. The semiconductor structure of claim 2, wherein the conductive material is tungsten, ruthenium, iridium, molybdenum, or copper; the outer liner is made of titanium, titanium-nitride, tantalum, or tantalum-nitride; and the inner liner is made of ruthenium, ruthenium-tantalum, iridium, iridium-tantalum, cobalt, or cobalt-tantalum.

6. The semiconductor structure of claim 1, wherein sidewalls of the bottom portion lean inwardly and sidewalls of the top portion lean outwardly.

7. The semiconductor structure of claim 1, wherein a horizontal cross-sectional area of the metal via at a bottom of the top portion is smaller than or equal to a horizontal cross-sectional area of the metal via at a top of the bottom portion.

8. A method of forming a semiconductor structure, the method comprising:
forming a first portion of a metal via with a conductive material, the first portion of the metal via having a conical frustum shape and being formed on top of a metal line;
covering the first portion of the metal via with a dielectric layer;
creating an opening in the dielectric layer, the opening exposing a top surface of the first portion of the metal via;
forming an outer liner covering sidewalls of the opening;
forming an inner liner on top of and covering the outer liner; and
filling the opening surrounded by the inner liner with the conductive material to form a second portion of the metal via.

9. The method of claim 8, wherein forming the first portion of the metal via comprises:
depositing a layer of the conductive material on top of the metal line; and
patterning the layer of the conductive material, through a subtractive patterning process, by removing a portion of the layer of the conductive material to cause a remaining portion of the layer of the conductive material to form the first portion of the metal via.

10. The method of claim 8, wherein forming the outer liner comprises:
depositing a conformal layer of a first liner material covering the sidewalls of the opening and the exposed top surface of the first portion of the metal via; and
removing a horizontal portion of the conformal layer of the first liner material to expose the top surface of the first portion of the metal via, thereby leaving the conformal layer of the first liner material at the sidewalls of the opening to form the outer liner.

11. The method of claim 10, wherein removing the horizontal portion of the conformal layer further comprises removing a portion of the first portion of the metal via exposed by the removal of the horizontal portion of the conformal layer to create a recess in the first portion of the metal via.

12. The method of claim 11, wherein forming the inner liner comprises forming the inner liner covering sidewalls of the recess in the first portion of the metal via.

13. The method of claim 12, wherein filling the opening surrounded by the inner liner comprises filling the recess with the conductive material to form a bottom portion of the metal via with rest of the first portion of the metal via, and filling the opening surrounded by both the inner liner and the outer liner with the conductive material to form a top portion of the metal via.

14. The method of claim 8, wherein the metal line is embedded in an interlevel-dielectric (ILD) layer, further comprising forming a cap layer on top of the ILD layer, the cap layer surrounding a bottom section of the first portion of the metal via.

15. The method of claim 14, wherein forming the cap layer comprises:
depositing a layer of capping material covering the first portion of the metal via and on top of the ILD layer;
planarizing the layer of capping material through a chemical-mechanical-polishing (CMP) process to expose a top surface of the first portion of the metal via; and
recessing the layer of capping material to form the cap layer, wherein a top surface of the cap layer is below the top surface of the first portion of the metal via.

16. A semiconductor structure comprising:
a metal via having a bottom portion and a top portion; and
a dielectric layer surrounding the metal via,
wherein the bottom portion of the metal via has a conical frustum shape and is directly surrounded by the dielectric layer, and the top portion of the metal via has an inverted conical frustum shape and includes an outer liner and an inner liner at sidewalls thereof.

17. The semiconductor structure of claim 16, wherein a central portion of the top portion and the bottom portion comprise a same conductive material, and the conductive material extends continuously from the top portion to the bottom portion.

18. The semiconductor structure of claim 17, wherein the central portion of the top portion is directly surrounded by the inner liner, the inner liner is surrounded by the outer liner, and the outer liner is surrounded by the dielectric layer.

19. The semiconductor structure of claim 18, wherein a portion of the inner liner extends into the bottom portion but stays away from sidewalls of the bottom portion.

20. The semiconductor structure of claim 16, wherein sidewalls of the bottom portion lean inwardly and the sidewalls of the top portion lean outwardly.
